(19) United States
(12) Patent Application Publication
(10) Pub. No.: US 2007/0064404 A1
(43) Pub. Date: Mar. 22, 2007

(54) Toolless circuit board mount

(76) Inventor: Ronald Paul Dean, Fort Collins, CO (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 11/232,795

(22) Filed: Sep. 21, 2005

(51) Int. Cl. H05K 7/04; H05K 7/02

(52) U.S. Cl. 361/810

(57) ABSTRACT

A system and method for mounting a printed circuit board in an electronic equipment enclosure allows installation and removal of the board without the use of tools. In a preferred embodiment, standoffs attached to the printed circuit board engage keyhole slots in a wall of the enclosure. A locking device pivotally attached to the wall is rotated from an unlocked position to a locked position, acting as a over center cam during the rotation. A face on the locking device engages an edge of the circuit board, constraining the circuit board in the enclosure.

### FIELD OF THE INVENTION

The present invention relates to electronic equipment, and more specifically to mounting a printed circuit board into an electronic equipment enclosure.

### BACKGROUND

In many types of electronic equipment, and especially in modem computers, it is common for one or more printed circuit boards to be mounted in an enclosure. For example, a motherboard in a computer is often mounted parallel to one wall of an enclosure. Often, the mounting is accomplished by passing threaded fasteners through the board and through standoffs that hold the board apart from the enclosure wall. Mounting a circuit board using threaded fasteners is time consuming, and makes servicing of the equipment time consuming and difficult as well.

Various other schemes have been devised for mounting circuit boards in enclosures, each scheme having its own disadvantages.

### BRIEF DESCRIPTION OF THE DRAWINGS

FIG. 1 shows a circuit board mounting system in accordance with an example embodiment of the invention.

FIG. 2 shows reverse perspective view of the circuit board shown in the example system of FIG. 1.

FIG. 3 illustrates some steps in the assembly of the example system of FIG. 1.

FIG. 4 illustrates the operation of a locking device in the example system of FIG. 1.

FIG. 5 is a detail view of a standoff in accordance with an example embodiment of the invention.

FIGS. 6A and 6B are cutaway top views of a locking device in accordance with a second example embodiment of the invention, in unlocked and locked positions, respectively.

### DETAILED DESCRIPTION

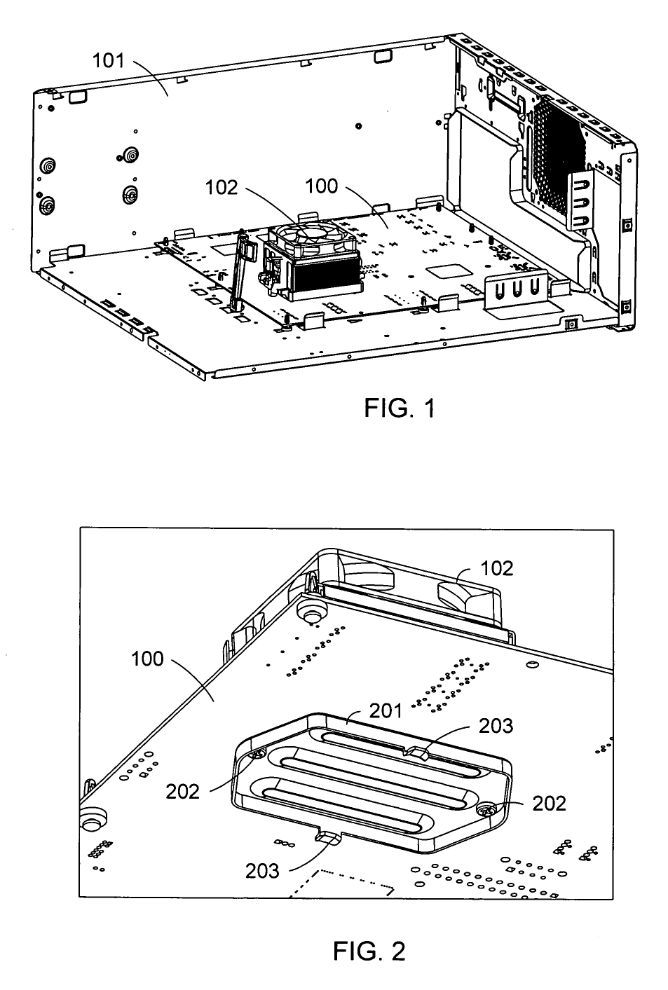

FIG. 1 shows a circuit board mounting system in accordance with an example embodiment of the invention. A printed circuit board 100 is mounted in enclosure 101. In the example embodiment of FIG. 1, enclosure 101 is a computer enclosure, but the invention may be embodied in other kinds of electronic equipment as well. Enclosure 101 is preferably made of sheet metal, and comprises various holes, tabs, and other features for mounting other components. Many parts of the computer of FIG. 1 are omitted for clarity.

Circuit board 100 may comprise many electronic components, including integrated circuits, connectors, and discrete components. Most such devices have been omitted from the figures. Some of the devices on circuit board 100 may generate significant heat while in operation, and require heat dissipation mechanisms. In FIG. 1, heat dissipating module 102 attaches to circuit board 100 and removes heat from a microprocessor (which is obscured by module 102). Example heat dissipating module 102 comprises a heat sink for drawing heat away from the microprocessor, and a fan for facilitating dissipation of the heat into the interior of enclosure 101. Other mechanisms may direct airflow through enclosure 101 so that heat is carried outside enclosure 101.

A heat dissipating module such as module 102 is relatively massive as compared with other components on circuit board 100. During shipping or other periods of vibration, mechanical shock, or other dynamic loading, module 102 exerts significant forces on its mountings. Circuit board 100 may be made of materials chosen for their electrical properties, and may not be intended to withstand these mechanical loads. Preferably, module 102 is mounted in such a way that it is constrained by components other than circuit board 100 during periods of dynamic loading.

FIG. 2 shows reverse perspective view of the circuit board shown in the example system of FIG. 1. Backing plate 201 has been previously attached to the underside of circuit board 100 by screws 202, which extend into heat dissipating module 102. Backing plate 201 comprises tabs 203 for attaching to enclosure 101.

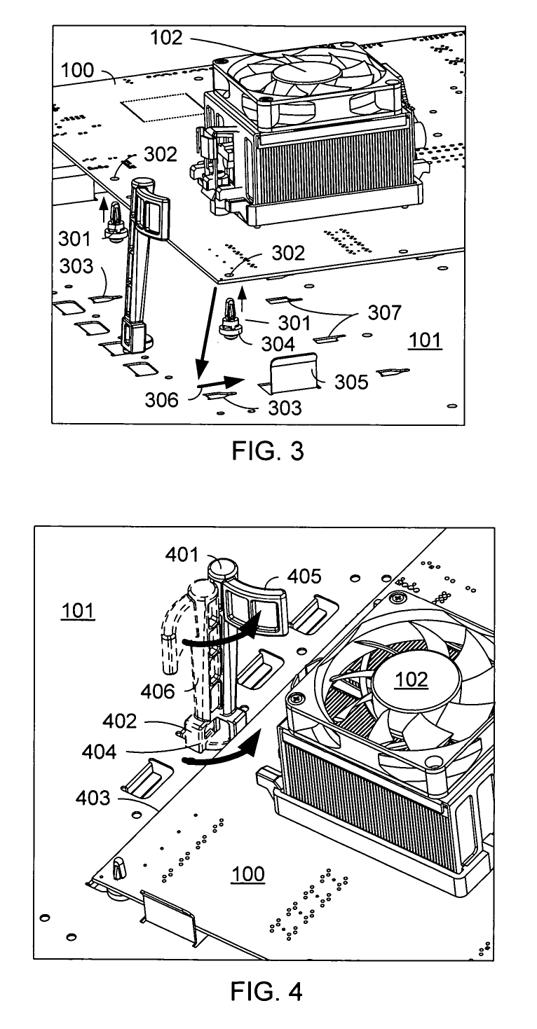

FIG. 3 illustrates some steps in the assembly of the example system of FIG. 1. Standoffs 301 are snapped into holes 302 in circuit board 100. Standoffs 301 are preferably made of a molded plastic such as polycarbonate, nylon, acrylonitrile butadiene styrene (ABS) or another suitable material having sufficient strength an flexibility. A molded plastic standoff may include a filler material, such as fiberglass, to enhance its properties. Several standoffs 301 may be used. For example, 10 each of standoffs 301 may be snapped into circuit board 100. Alternatively, standoffs 301 may be heat staked onto circuit board 100, or attached using fasteners, or attached in some other way.

The assembly comprising circuit board 100, heat dissipating module 102, and standoffs 301 is inserted into enclosure 101 so that standoffs 301 protrude partially through keyhole slots 303 in a wall (in this example, the floor) of enclosure 101. Shoulder 304 on each standoff 301 keeps standoff 301 from falling through the enclosure floor. One or more guiding tabs such as tab 305 may assist in guiding circuit board 100 into position so that standoffs 301 and keyhole slots 303 are properly aligned for assembly. The assembly is then slid in the direction of arrow 306.

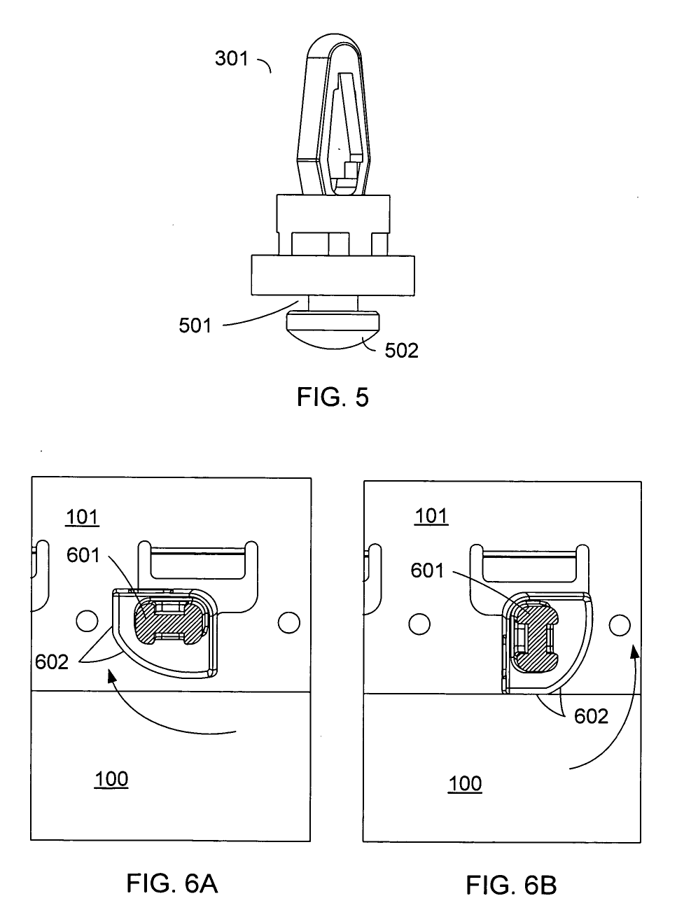

FIG. 5 is a detail view of a standoff 301. A groove 501 in each standoff 301 nests in the narrow end of each keyhole slot 303. The enlarged lower end 502 of each standoff constrains the assembly in the vertical direction. The assembly is thus constrained in all axes of motion except the sliding direction.

Referring again to FIGS. 2 and 3, during the insertion of standoffs 301 in keyhole slots 303, tabs 203 of backing plate 201 engage slots 307 of enclosure 101. Heat dissipation module 102 is thus constrained by enclosure 101, so that the module does not exert undue force on circuit board 100 during vibration or mechanical shock.

FIG. 4 illustrates the operation of a locking device in the example system of FIG. 1. In the example embodiment, locking device 401 is preferably made of a molded plastic such as glass-filled polycarbonate. Example locking device 401 comprises an elongate body 406, and is preferably pivotally attached at an attachment end to enclosure 101 using a threaded fastener such as a screw, although other attachment means could be used. Locking device 401 further comprises a lever at a lever end opposite the attachment end. Actuation of locking device 401 completes the mechanical installation of circuit board 100 into enclosure 101. During insertion of circuit board 100, locking device 401 is kept in the position indicated by broken lines. Once circuit board 100 is slid into position, locking device 401 is turned, using lever 405, to the locked position indicated by solid lines. In the locked position, face 402 engages edge 403 of circuit board 100, thereby constraining board 100 in the remaining axis of motion.

During the rotation of locking device 401, face corner 404 interferes slightly with circuit board 100. Compliance present in circuit board 100, enclosure 101, and locking device 401 allows the rotation to be completed. Locking device 401 stays in the locked position because normal vibration or mechanical shock will not cause locking device 401 to overcome the resistance to rotation imposed by friction and the interference with circuit board 100. The locking action may be thought of as the operation of an over center cam. The result is a secure installation of circuit board 100 into enclosure 101 without the use of tools.

The installation procedure may be reversed in order to remove circuit board 100 for service or replacement. To remove circuit board 100, locking device 401 is rotated to its unlocked position. Friction and interference are overcome by the person actuating locking device 401. Once locking device 401 is in its unlocked position, the assembly comprising circuit board 100, standoffs 301, and heat dissipation module 102 is slid in the direction opposite arrow 306 and lifted out of enclosure 101.

One of skill in the art will recognize that the embodiment so far described is exemplary only, and variations are possible within the scope of the appended claims. For example, circuit board 100 need not be installed on the floor of enclosure 101, but may be installed on a surface in a different orientation, such as a vertical wall. Various parts may be made of different materials than those given as examples. For example, standoffs 301 or locking device 401 may be molded of a different kind of plastic. Locking device 401 could be stamped from sheet metal, die cast, or made by some other process from other materials.

Similarly, the shape of the portion of the locking device that contacts circuit board 100 may differ from the shape of example locking device 401, while still operating as an over center cam. FIGS. 6A and 6B are cutaway top views of a locking device 601 in accordance with a second example embodiment of the invention, in unlocked and locked positions, respectively. A continuous face 602, seen edge-on in the figures, drives printed circuit board 100 into its final position as locking device 601 is rotated into its locked position. The transition from the curved to flat portions of face 601 provide an over center cam action. While both locking device 401 and locking device 601 comprise flat surface portions that engage the edge of circuit board 100 when either locking device is in the locked position, such surface or surface portion need not be flat. One of skill in the art may envision a curved surface that provides an over center cam action and constrains circuit board 100.

1. A circuit board mounting system, comprising:
an electronic equipment enclosure having a wall, the wall further comprising keyhole slots;
a printed circuit board;
standoffs attached to the printed circuit board, each standoff comprising a groove for engaging one of the keyhole slots; and
a locking device pivotally attached to the wall and comprising a surface for engaging an edge of the printed circuit board, the surface engaging the printed circuit board edge and constraining the printed circuit board when the locking device is in a locked position, the locking device operating as an over center cam during rotation from an unlocked position to the locked position.

2. The circuit board mounting system of claim 1, further comprising:
a relatively massive component mounted on a first side of the printed circuit board; and
a backing plate mounted to a second side of the printed circuit board, opposite the relatively massive component and secured to the relatively massive component, the backing plate comprising tabs configured to engage slots in the enclosure wall.

3. The circuit board mounting system of claim 2, wherein the relatively massive component comprises a heat sink.

4. The circuit board mounting system of claim 2, wherein the relatively massive component comprises a fan.

5. The circuit board mounting system of claim 1, further comprising guiding tabs for facilitating the alignment of the standoffs with the keyhole slots.

6. The circuit board mounting system of claim 1, wherein the surface engaging the printed circuit board edge is substantially flat.

7. A locking device for securing a circuit board in an electronic equipment enclosure, comprising:
a body having an attachment end and a lever end opposite the attachment end, the attachment end configured to enable pivotal attachment of the locking device to a wall of the enclosure;
a face configured to engage an edge of a printed circuit board when the locking device is rotated to a locked position, thereby constraining the printed circuit board in the enclosure.

8. The locking device of claim 7, wherein the face is substantially flat.

9. The locking device of claim 7, wherein, when the locking device is rotated from an unlocked position to a locked position, the locking device operates as an over center cam during the rotation.

10. A method, comprising:
attaching standoffs to a printed circuit board, each standoff comprising a groove configured to engage a keyhole slot in a wall of an electronic equipment enclosure;
engaging the standoff grooves with the keyhole slots;
sliding the printed circuit board in a direction substantially parallel to the wall;
rotating a locking device from an unlocked position to a locked position, the locking device pivotally attached to the wall, the locking device operating as an over center cam and comprising a face configured to engage an edge of the printed circuit board after the rotation, thereby constraining the printed circuit board.

11. The method of claim 10, further comprising rotating the locking device from the locked position to the unlocked position and removing the printed circuit board from the enclosure.
